(19) United States
(12) Patent Application Publication
(10) Pub. No.: US 2015/0138450 A1
(43) Pub. Date: May 21, 2015

(54) DISPLAY APPARATUS AND TELEVISION RECEIVER

(71) Applicant: SHARP KABUSHIKI KAISHA, Osaka-shi, Osaka (JP)

(72) Inventor: Manabu Shimokobe, Osaka-shi (JP)

(73) Assignee: SHARP KABUSHIKI KAISHA, Osaka-shi, Osaka (JP)

(21) Appl. No.: 14/402,298

(22) PCT Filed: May 15, 2013
(86) PCT No.: PCT/JP2013/063523

§ 371 Date: Nov. 19, 2014

(30) Foreign Application Priority Data
May 21, 2012 (JP) 2012-115766

(51) Int. Cl. H04N 5/64; A47B 81/06; H05K 5/00

(52) U.S. Cl. CPC H04N 5/64; H05K 5/0017; A47B 81/06
USPC 348/843

(57) ABSTRACT

The rear cabinet of the television receiver (display apparatus) is constituted by multiple pieces connected with screws. A circumferential part along one side of one piece is overlapped with the other piece to be connected. The other piece is provided with an overlap part overlapped with the inner surface of the circumferential part, the first rib along one side and a parallel member protruding to be in parallel with the outer surface, the first rib and the parallel member reinforcing the piece. The first rib is provided with a boss into which a screw is inserted, and the parallel member is disconnected at the position of the boss. The second rib is further provided so as to enclose the boss, which reinforces the part without the parallel member.

This application is the National Phase of PCT International Application No. PCT/JP2013/063523, filed on May 15, 2013, which claims priority under 35 U.S.C. 119(a) to Patent Application No. 2012-115766, filed in Japan on May 21, 2012, all of which are hereby expressly incorporated by reference into the present application.

### BACKGROUND

1. Technical Field

The present invention relates to a thin and large display apparatus and a television receiver.

2. Description of Related Art

In recent years, a display apparatus used in a television receiver, an information display or the like is often thin and is provided with a display panel such as a liquid-crystal panel or an electro luminescence (EL) panel. A thin-type display apparatus has a rectangular flat display section including a display panel attached to a chassis, and is provided with a front cabinet of a rectangular frame shape on the front side of the display section as well as a rear cabinet covering the rear surface of the display section. In recent years, a larger and thinner display apparatus such as a 90-inch type has been developed. Since the front cabinet and rear cabinet tend to have low strength because of their thin wall surfaces, a rib for reinforcement is provided inside the cabinets. Japanese Patent Application Laid-Open Publication No. 2005-268868 discloses a display apparatus in which a rib for reinforcement is provided on an inner wall surface of a cabinet.

### SUMMARY OF THE INVENTION

A large display apparatus such as a 90-inch type has a massive-sized rear cabinet which is difficult to be manufactured in one piece. The rear cabinet is thus manufactured in pieces and the individually-manufactured pieces are connected with screws to form the rear cabinet. As a connection part between the pieces likely to have insufficient strength, it is necessary to provide a reinforcement member in order to maintain the strength. At a connection part, however, it is necessary to form a boss for receiving a screw for connection, which makes it difficult to provide the reinforcement member at the same location as the boss. This may cause the part with the boss in the connection part to have insufficient strength.

The present invention has been made in view of the circumstances described above. An object of the invention is to provide a display apparatus and a television receiver in which a reinforcement member is appropriately arranged to prevent the connection part of the rear cabinet from having insufficient strength.

A display apparatus according to the present invention is characterized by comprising: a rectangular display section for displaying an image on a front side; a frame-shaped front cabinet located at the front side of the display section; and a rectangular plate-shaped rear cabinet located on a rear side of the display section, wherein the rear cabinet is constituted by connecting a plurality of rectangular plate-shaped pieces with a plurality of screws, parts of the pieces being overlapped with each other, one of any two pieces to be connected among the plurality of the pieces, including: a circumferential part along one side; and a plurality of through holes into which the plurality of screws are inserted respectively, which are formed at a circumferential part, the other of the two pieces, including: an overlap part protruding from one side of a rear surface, in parallel with the rear surface, at a position closer to an front side than the rear surface so as to be overlapped with the front surface of the circumferential part; a first rib provided on the front surface of the overlap part along said one side; a parallel member, which is along said one side, protruding from the first rib to be in parallel with the rear surface in a same direction as the overlap part; and a plurality of bosses provided being joined to a surface of the first rib on a side where the parallel member protrudes, each of the plurality of bosses being provided with a hole for receiving each of the plurality of screws at an end opposite to each of the plurality of through holes, and the parallel member is disconnected at a portion of the first rib where one of the plurality of bosses is joined.

The display apparatus according to the present invention is characterized in that the other of the two pieces, further includes a second rib so bent as to enclose a reverse side of the first rib at the portion where one of the plurality of bosses is joined, which is provided on an front surface of the overlap part, and the second rib is coupled to the reverse side of the first rib at a portion where the parallel member protrudes on both sides of the portion where one of the plurality of bosses is joined.

The display apparatus according to the present invention is characterized in that the other of the two pieces, further includes more than one of the second ribs.

The display apparatus according to the present invention is characterized in that said one of the two pieces, further includes a third rib being in parallel with the first rib and in contact with the parallel member, which is provided on the front surface.

The display apparatus according to the present invention is characterized in that a portion at a protruding end of the overlap part is inclined from a rear side toward an front side.

The display apparatus according to the present invention is characterized in that the other of the two pieces, further includes a protruding part protruding from the first rib in a same direction as the overlap part, which is joined to the end of each of the plurality of bosses and has a predetermined length along said one side.

The display apparatus according to the present invention is characterized in that said one of the two pieces, further includes a third rib being in parallel with the first rib and in contact with the parallel member, which is provided on the front surface, and a portion of the third rib opposite to the protruding part has a shape of avoiding the protruding part on the front surface of said one of the two pieces.

A television receiver according to the present invention is characterized by comprising: the display apparatus according to the present invention; and a receiving section for receiving television broadcasts, wherein the display apparatus displays an image based on the television broadcasts received by the receiving section.

In the present invention, the rear cabinet included in the display apparatus (television receiver) is constituted by multiple pieces being connected with screws. One of the pieces to be connected is provided with a band-like circumferential part including one side. The other one of the pieces is provided with an overlap part which is overlapped with the circumferential part from the rear side, the first rib formed along one side and a parallel member protruding from the first rib to be in parallel with an outer surface. The first rib and the parallel member reinforce the pieces. The first rib is provided with a boss into which a screw for connecting the pieces with each other is inserted, while the parallel member is disconnected at the position of the boss. The second rib is further provided which bends to enclose the boss at a position closer to the middle of the piece than the first rib and which is coupled to the parallel member. The second rib reinforces the part without the parallel member.

Moreover, in the present invention, a piece of the rear cabinet is provided with multiple second ribs. At the portions where multiple bosses are respectively formed, the second ribs serve to reinforce the piece.

Furthermore, in the present invention, the third rib along one side is provided on the inner surface of one of the pieces to be connected. The third rib is in parallel with the first rib of the other one of the pieces, and is in contact with the parallel member. This reinforces the connection part of the two pieces.

Furthermore, in the present invention, the edge of the overlap part is formed as a slope inclined from the outer side to the inner side. At the time of assembly work of the rear cabinet by connecting the pieces, an end of the third rib of one piece slides along the slope of the other piece, making the pieces aligned with each other.

According to the present invention, insufficiency in strength at a connection part between multiple pieces constituting the rear cabinet is prevented and the rear cabinet is properly maintained in its strength even with the structure in which multiple pieces are connected, thereby producing a beneficial effect.

The above and further objects and features of the invention will more fully be apparent from the following detailed description with accompanying drawings.

### BRIEF DESCRIPTION OF THE SEVERAL VIEWS OF THE DRAWINGS

FIG. 1 is a schematic perspective view of a television receiver;

FIG. 2 is a schematic exploded perspective view of a television receiver;

FIG. 3 is a rear view of a rear cabinet;

FIG. 4 illustrates rear views of respective pieces;

FIG. 5 is an enlarged partial front view of connection parts of the pieces of the rear cabinet, separated from each other;

FIG. 6 is an enlarged partial rear view of connection parts of the pieces of the rear cabinet, separated from each other;

FIG. 7 is an enlarged partial perspective view of the connection parts of the pieces of the rear cabinet, separated from each other;

FIG. 8 is an enlarged perspective view of the inner side of the connection parts of the pieces of the rear cabinet;

FIG. 9 is a cross section view taken from the line IX-IX in FIG. 8; and

FIG. 10 is a schematic cross section view illustrating a state in the middle of a work of connecting a piece with another piece.

### DETAILED DESCRIPTION

The present invention will now be described in detail with reference to the drawings illustrating an embodiment thereof.

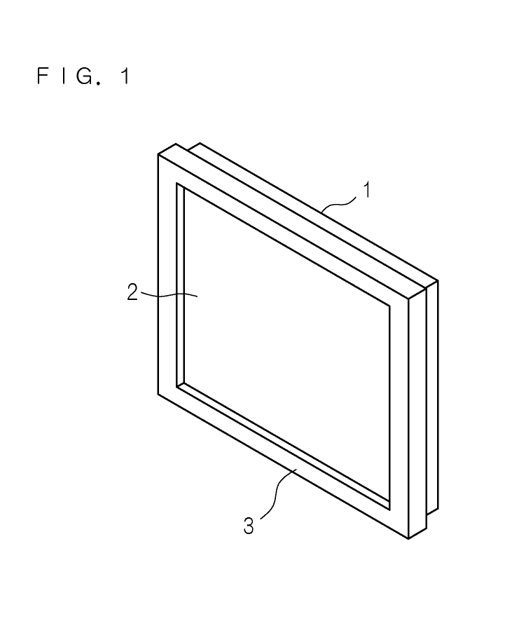

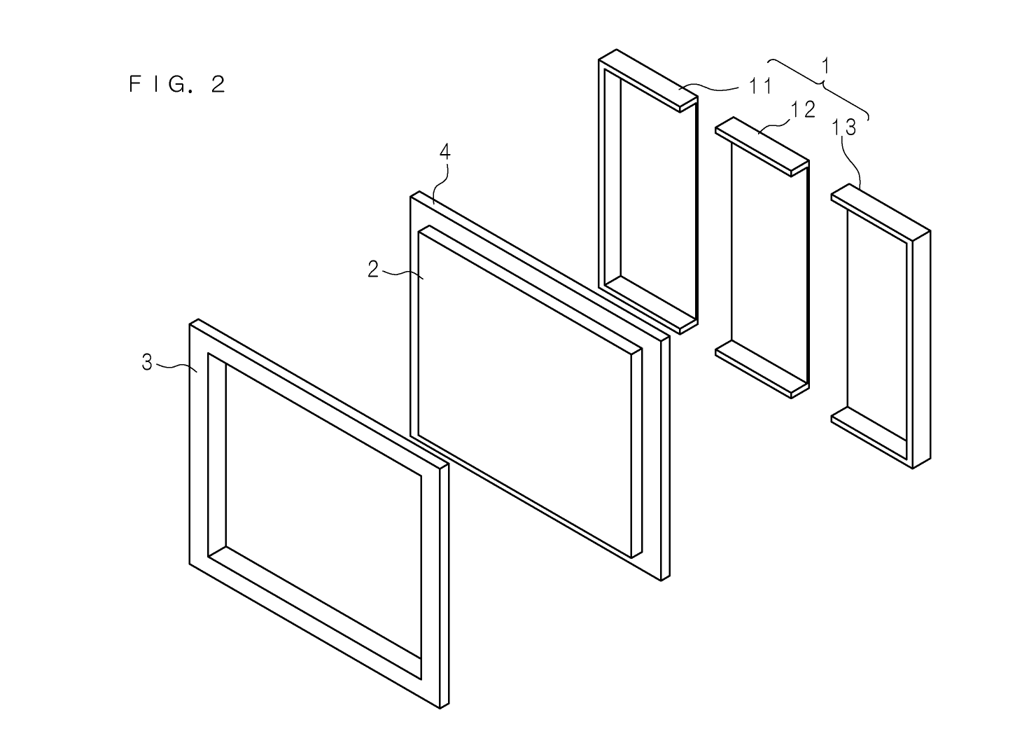

FIG. 1 is a schematic perspective view of a television receiver, and FIG. 2 is a schematic exploded perspective view of a television receiver. The television receiver is, for example, a 90-inch television receiver, which is provided with the display apparatus according to the present invention. The television receiver is provided with a display section 2 of a rectangular flat shape including a display panel such as a liquid-crystal panel or an EL panel, the display section 2 being fixed to a chassis 4 made of metal. The display section 2 includes a back light, an image processing circuit and the like. Moreover, the television receiver is provided with, at the front side of the display section 2, a front cabinet 3 having a rectangular frame shape. The front cabinet 3 is formed with metal or resin, and is fixed to the chassis 4. The circumferential parts of the display section 2 and chassis 4 are covered with the front cabinet 3. The front cabinet 3 may be constituted by multiple parts. Furthermore, the television receiver is provided with a rear cabinet 1 which covers the rear surfaces of the display section 2 and chassis 4. The television receiver further includes other components such as a receiving section, an input/output interface, a control circuit board, a speaker and a power supply (not illustrated), which are fixed to the chassis 4. The receiving section (not illustrated) receives television broadcasts, while the display section 2 displays an image based on the television broadcasts received at the receiving section. It is noted that the television receiver may have a receiving section as a separate unit.

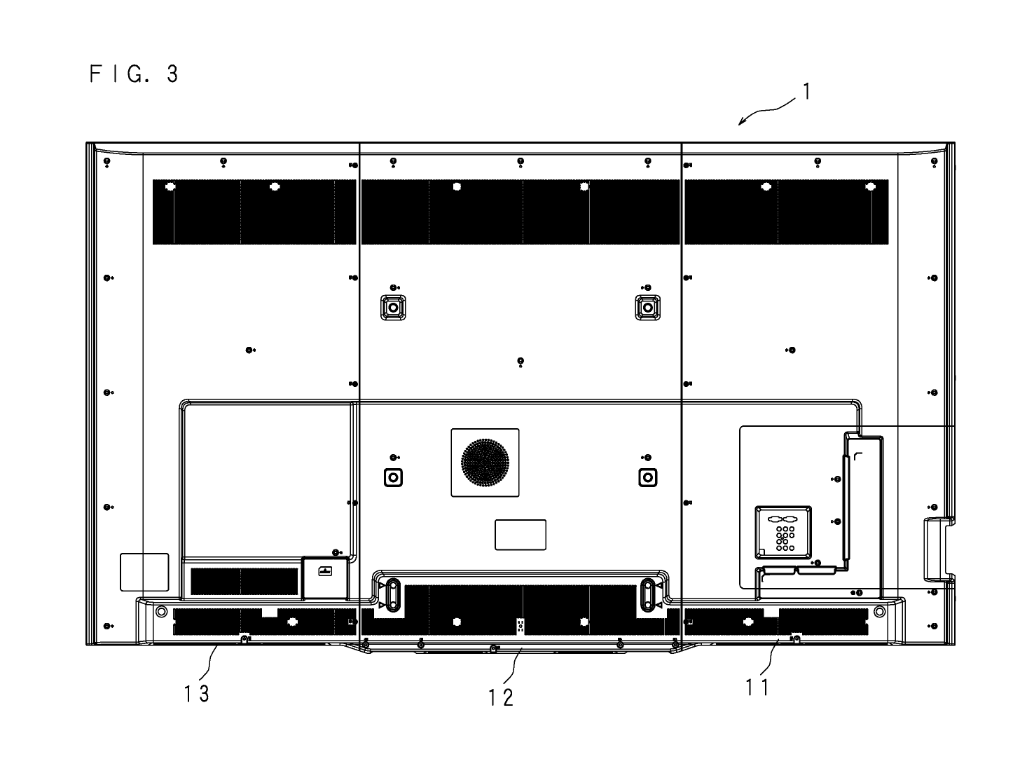

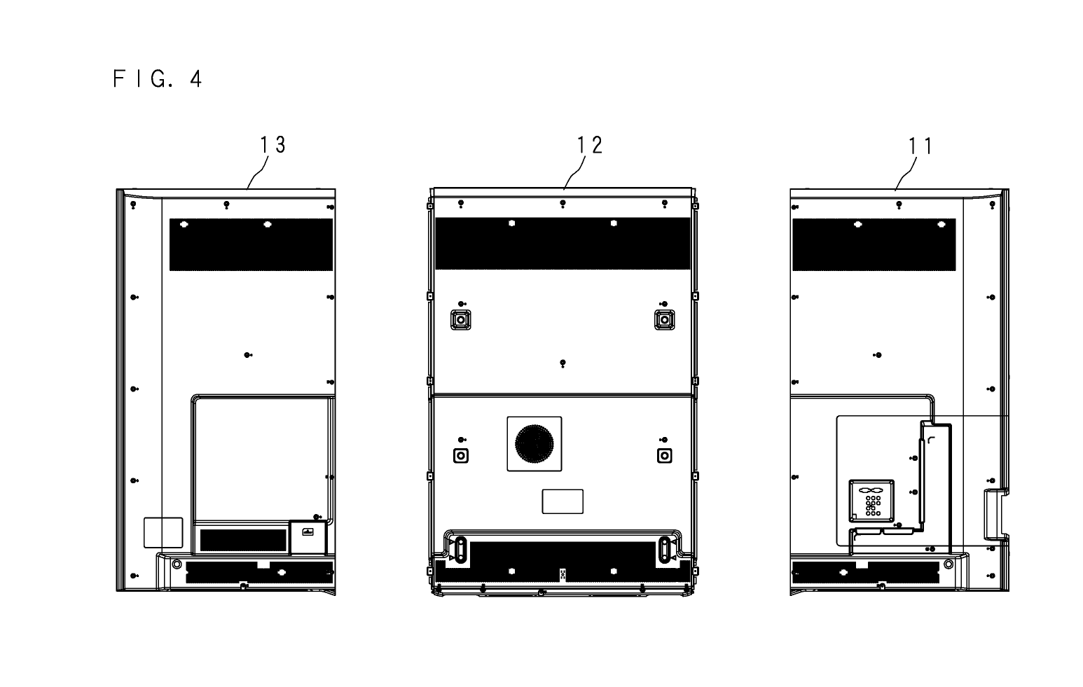

FIG. 3 is a rear view of the rear cabinet 1. The rear surface of the television receiver serves as an outer surface of the rear cabinet 1. The rear cabinet 1 is formed with resin to have a rectangular shape as a whole. Since the rear cabinet 1 is massive in size compared to other components of the television receiver and thus is difficult to be formed in one piece, it is manufactured by being parted in three pieces 11, 12 and 13. FIG. 4 illustrates the respective rear views of the three pieces 11, 12 and 13. Each of the pieces 11, 12 and 13 has a rectangular shape obtained by cutting the entire rear cabinet 1 in the short side direction. The pieces 11, 12 and 13 are connected with one another by multiple screws crossing on the outer surfaces and are assembled to be the rear cabinet 1. The rear cabinet 1 is constituted by connecting the pieces 11 and 12 with each other and by connecting the pieces 12 and 13 with each other. Furthermore, the rear cabinet 1 is fixed to the chassis 4 with screws. A part of the rear cabinet 1 may be latched to the front cabinet 3.

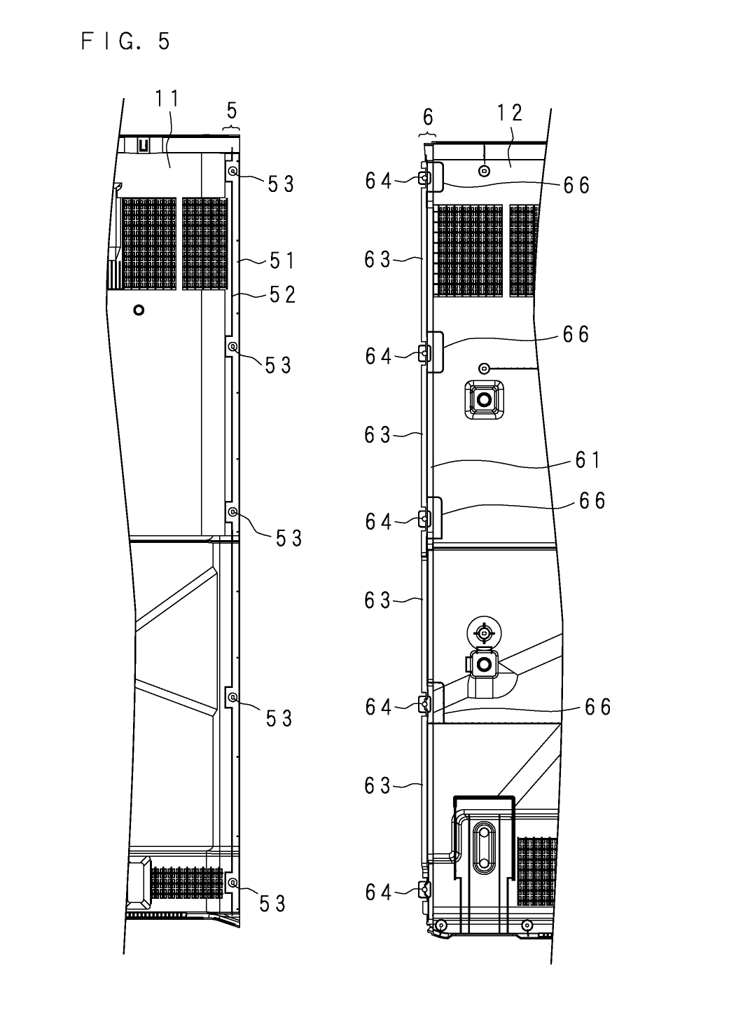

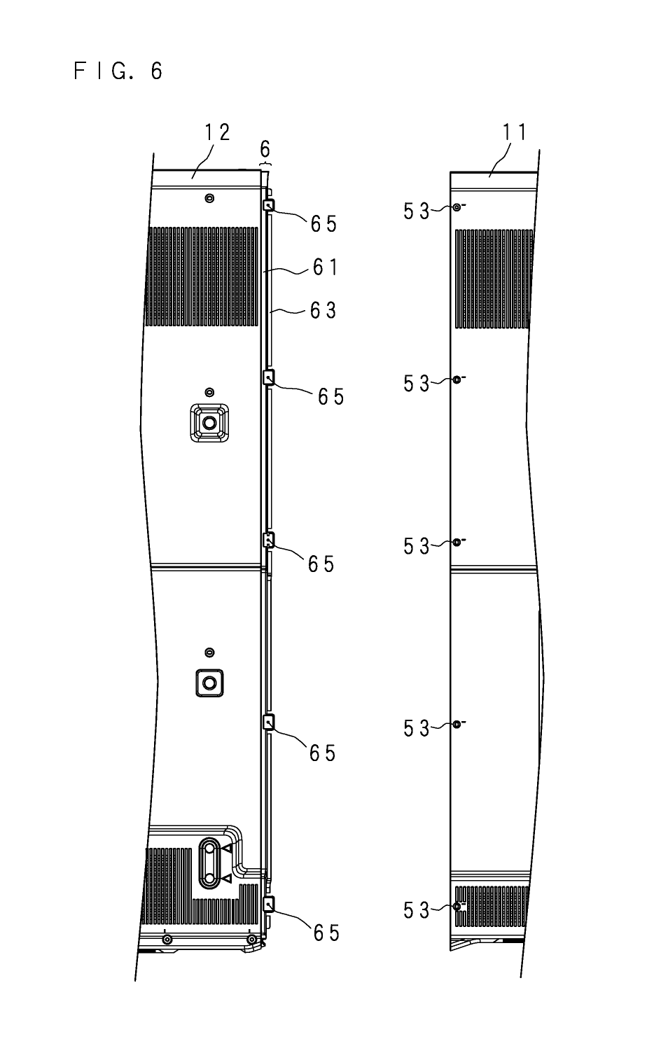

FIG. 5 is an enlarged partial front view of the connection parts of the pieces 11 and 12 of the rear cabinet 1, separated from each other. The front side of the television receiver corresponds to the inner side of the rear cabinet 1. FIG. 6 is an enlarged partial rear view of the connection parts of the pieces 11 and 12 of the rear cabinet 1, separated from each other. A connecting part 5 is provided at one side of the piece 11, whereas a connecting part 6 is provided at one side of the piece 12. The connecting parts 5 and 6 are connected, overlapped with each other, with multiple screws, so as to connect the pieces 11 and 12 with each other. The present embodiment illustrates a form where the pieces 11 and 12 are so connected that the connecting part 5 of the piece 11 is arranged more toward the rear side than the connecting part 6 of the piece 12. Furthermore, another connecting part for connection with the piece 13 is provided at another side of the piece 12.

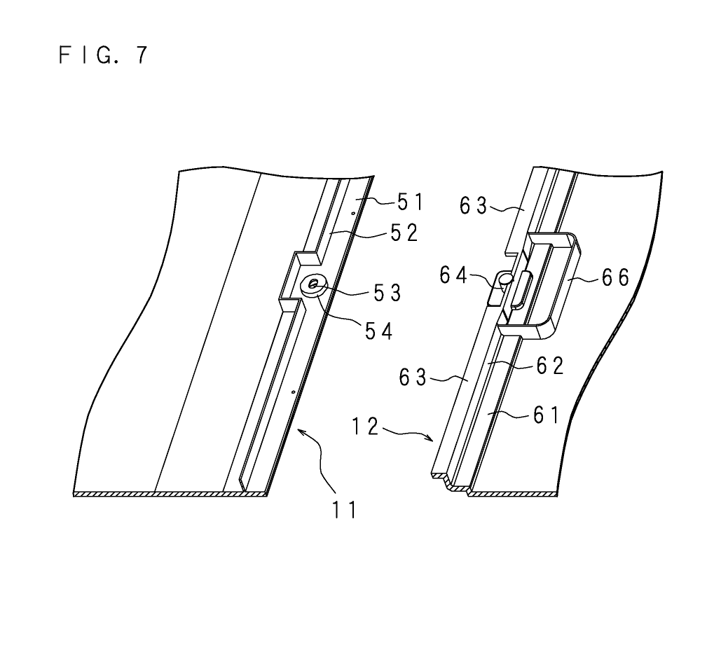

FIG. 7 is an enlarged partial perspective view of the connection parts of the pieces 11 and 12 of the rear cabinet 1, separated from each other. The connecting part 5 includes a band-like circumferential part 51 along one side of the piece 11. The circumferential part 51 corresponds to one side part of the piece 11 including a region closer to the inner side from one side of the outer surface by a predetermined width. The thickness of the circumferential part 51 is equal to the thickness of the main part of the piece 11. The connecting part 5 further includes a third rib 52 protruding from the inner surface by a certain length and being parallel to a side of the piece 11 at a position away from the end of the inner surface by a predetermined distance. By protruding from the inner surface, the third rib 52 protrudes toward the front direction of the television receiver. Moreover, as the third rib 52 protrudes from the inner surface, it reinforces the piece 11 which is formed in a thin plate shape as a whole. The third rib 52 also serves as a boundary between the circumferential part 51 and a portion of the piece 11 other than the connecting part 5.

Furthermore, a boss 54 formed to be convex from the inner surface toward the front side is provided at the inner side of the circumferential part 51. At the boss 54, a through hole 53 for receiving a screw inserting therethrough from the rear side is opened all the way from the outer surface to the inner surface of the circumferential part 51. Multiple bosses 54 and through holes 53 are aligned along the longitudinal direction of the circumferential part 51. In the state where the pieces 11 and 12 are connected together, the boss 54 is formed to be convex toward the connecting part 6 of the piece 12. Around the boss 54, the third rib 52 is located farther away from the side of the piece 11 compared to the other parts thereof, and has a shape of avoiding the boss 54 on the inner surface.

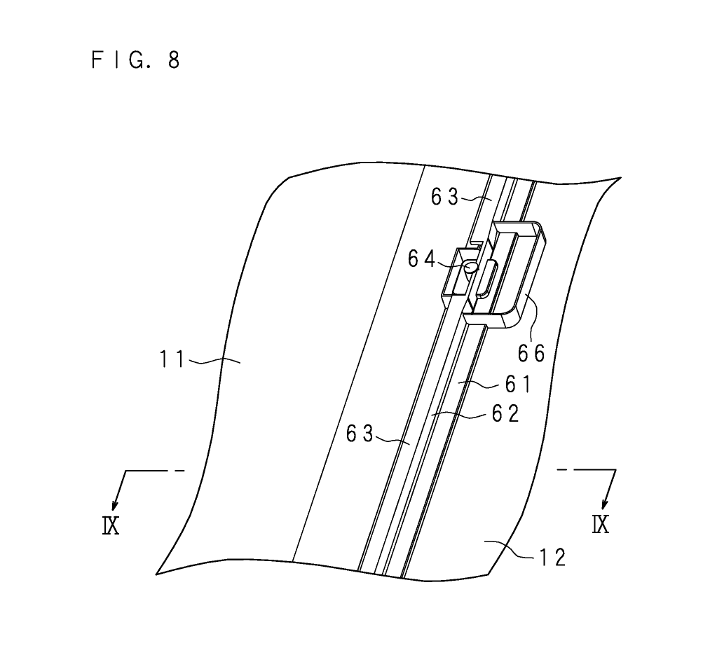

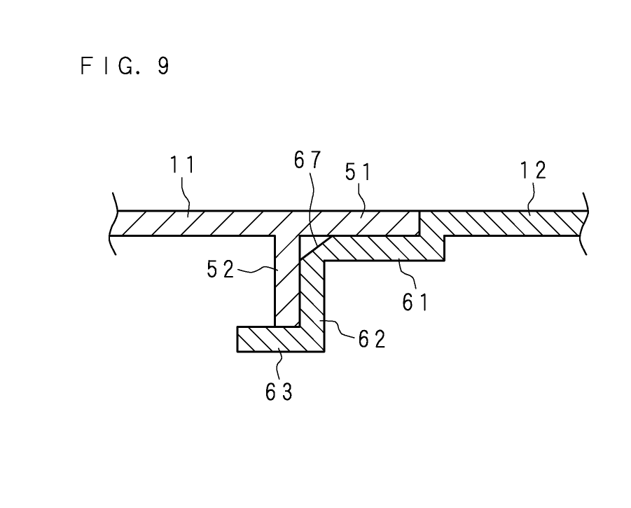

The connecting part 6 is a band-like part protruding from one side of the rectangular piece 12. FIG. 8 is an enlarged perspective view of the inner side of the connection parts of the pieces 11 and 12 of the rear cabinet 1, and FIG. 9 is a cross section view taken from the line IX-IX in FIG. 8. The upper side of FIG. 9 corresponds to the rear side of the television receiver, whereas the lower side corresponds to the front side thereof. As illustrated in FIGS. 6, 7 and 9, the connecting part 6 includes an overlap part 61 to be overlapped with the inner surface of the circumferential part 51. The overlap part 61 protrudes from one side of the outer surface of the piece 12 by a predetermined width to be in parallel with the outer surface, and has a band-like shape along one side. Furthermore, the overlap part 61 is provided at a position closer to the inner side than the outer surface of the piece 12 by the thickness of the circumferential part 51 so as to be overlapped with the inner surface of the circumferential part 51. In the state where the pieces 11 and 12 are connected with each other, the outer surface of the piece 11 and the outer surface of the piece 12 are substantially in the same plane, and the overlap part 61 is overlapped on the inner surface of the circumferential part 51.

Moreover, the connecting part 6 includes a first rib 62 protruding by a certain length vertically with respect to the inner surface from the protruding edge of the overlap part 61. The first rib 62 is formed along a side of the piece 12 and the longitudinal direction of the overlap part 61. By protruding vertically with respect to the inner surface, the first rib 61 protrudes toward the front direction of the television receiver. In the state where the pieces 11 and 12 are connected with each other, the first rib 62 is in parallel with the third rib 52.

Furthermore, the connecting part 6 includes a parallel member 63 protruding from the first rib 62 to be in parallel with the outer surface in the same direction as the overlap part 61. The parallel member 63 is formed to have a band-like shape along the first rib 62. The parallel member 63 is located at a position which is in contact with the protruding edge of the third rib 52. In the state where the pieces 11 and 12 are connected with each other, the third rib 52 is in parallel with the first rib 62, while the edge of the third rib 52 is in contact with the parallel member 63. By the first rib 62 protruding from the inner surface of the piece 12 and the parallel member 63 protruding from the first rib 62 to be in parallel with the outer surface, the first rib 62 and the parallel member 63 reinforce the end of the piece 12. Furthermore, by the third rib 52 being in contact with the parallel member 63, the connection part of the pieces 11 and 12 is reinforced.

The connecting part 6 is provided with multiple bosses 64 for receiving screws inserted from the rear side, and a screw hole 65 into which a screw is inserted is formed at each of the bosses 64. The screws inserting the through holes 53 from the rear side are screwed into the screw holes 65 and fixed, so as to connect the pieces 11 and 12 with each other. Note that the screws may also be fixed by another method, not limited to the method of screwing them into the screw holes 65.

The boss 64 has a shape vertical to the inner surface so that a screw is inserted vertically with respect to the outer surface of the piece 12, and is located to be joined with the first rib 62. The boss 64 is joined with the surface on the outer side of the first rib 62, i.e. the surface on the side from which the parallel member 63 protrudes. In practice, at the time of forming the piece 12, the bosses 64 are formed integrally with the first rib 62. As the boss 64 is formed integrally with the first rib 62, the part of the first rib 62 where the boss 64 is formed cannot be provided with the parallel member 63. Thus, the parallel member 63 is disconnected at both sides of the boss 64.

The piece 12 is provided with a second rib 66 vertical to the inner surface in the vicinity of each boss 64 on the inner surface. The second rib 66 is provided to be protruding from the inner surface of the piece 12 and from the inner surface of the overlap part 61 at a position closer to the middle of the piece 12 than the first rib 62. The second rib 66 has a U-shape in the front view so as to enclose the reverse side of the first rib 62 at the portion provided with the boss 64. The reverse side of the first rib 62 corresponds to the side on a surface opposite to the surface from which the parallel member 63 protrudes, i.e. the side toward the middle of the piece 12. Furthermore, the second rib 66 is coupled to the first rib 62 at two parts. The position at which the second rib 66 is coupled to the first rib 62 corresponds to the position on the reverse side of the first rib 62 at the portion where the parallel member 63 protrudes at both sides of the boss 64. In other words, the second rib 66 is coupled to the parallel member 63 on both sides of the bosses 64, and encloses the portion of the first rib 62 not having the parallel member 63 at a position closer to the middle of the piece 12 than the first rib 62. The second rib 66 provided as described above reinforces the portion of the piece 12 not having the parallel member 63.

As illustrated in FIG. 5, the portions of the piece 12 having the bosses 64 are not provided with the parallel member 63 but with the second ribs 66 respectively. By more than one second ribs 66 being provided, the piece 12 is more reinforced. It is not necessary to respectively form the second ribs 66 near all of the bosses 64. A part where sufficient strength is maintained by other structures may be formed without the second rib 66. Moreover, the second rib 66 in the front view may have any shape other than the U-shape as long as it is formed to enclose the part of the first rib 62 not having the parallel member 63 at a position inner than the first rib 62. For example, the second rib 66 may have a circular arc shape in the front view.

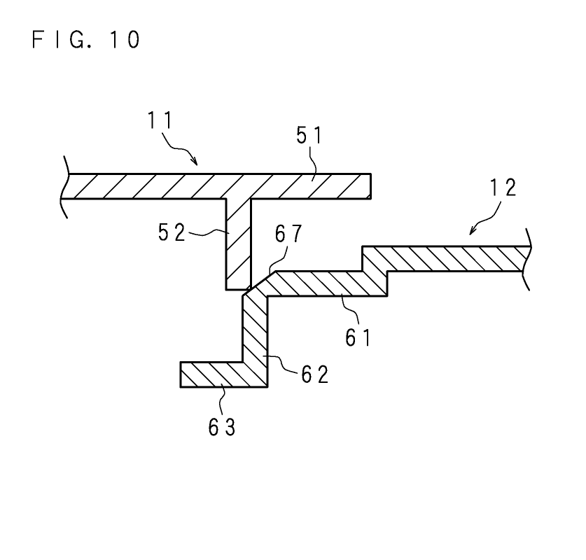

Furthermore, as illustrated in FIG. 9, the protruding edge of the overlap part 61 is formed as a slope 67 inclined from the outer side to the inner side of the piece 12. The slope 67 is an inclined surface for connecting the surface of the overlap part 61 overlapped with the circumferential part 51 and a surface of the first rib 62 opposed to the third rib 52. In the work of connecting the pieces 11 and 12, the worker conducts a work of making the piece 11 closer to the rear side of the piece 12 and making the circumferential part 51 overlapped with the overlap part 61. FIG. 10 is a schematic cross section view illustrating a state in the middle of a work of connecting the piece 11 with the piece 12. In the work of connecting, it is necessary to align the piece 11 with the piece 12 so that the circumferential part 51 is precisely overlapped with the overlap part 61. In such a case, as illustrated in FIG. 10, the piece 11 may be out of alignment and the edge of the third rib 52 may hit the overlap part 61. Here, the edge of the third rib 52 touches the slope 67 and slides along the slope 67, making the alignment of the pieces 11 and 12 smooth as illustrated in FIG. 9. Accordingly, the slope 67 being provided makes the work of connecting the pieces 11 and 12 easier and simplifies the assembly process of the rear cabinet 11 and the television receiver. The shape of the slope 67 is not limited to a shape with a certain inclination but may be a shape with variable inclinations at different positions such as a circular arc.

The connection part of the pieces 12 and 13 has a similar structure, in which the piece 13 is provided with a connecting part 5 while the piece 12 is provided with a connecting part 6 along another side, and the pieces 13 and 12 are connected with screws.

As described above, the rear cabinet 1 divided into multiple pieces is provided with the circumferential part 51 including one side of the piece 11 which is to be connected to another piece and the third rib 52 formed along the one side, the third rib reinforcing the piece 11. The other piece 12 is provided with the overlap part 61 to be overlapped with the inner surface of the circumferential part 51, the first rib 62 formed vertically with respect to the inner surface and along one side of the outer surface, and the parallel member 63 protruding from the first rib 62 to be in parallel with the outer surface. The first rib 62 and the parallel member 63 reinforce the piece 12. The first rib 62 is provided with the boss 64 which receives a screw inserted therein for connecting the pieces 11 and 12 with each other. The part of the first rib 62 having the boss 64 is not provided with the parallel member 63, which makes the piece 12 to have insufficient strength at this part. Thus, the second rib 66 vertical to the inner surface is formed to enclose the boss 64 at a position closer to the middle of the piece 12 than the first rib 62, and is coupled to the parallel member 63 on both sides of the boss 64. The second rib 66 serves to reinforce the part without the parallel member 63. This can prevent the strength of the connection part of the pieces constituting the rear cabinet 1 from being insufficient, and thus the rear cabinet 1 can appropriately maintain its strength even with the structure in which multiple pieces are connected with one another.

It is noted that the present embodiment illustrated an example where the pieces 11 and 13 are located more toward the rear side compared to the piece 12 at the connection parts of the rear cabinet 1. The positional relationship between the pieces is, however, not limited thereto but may be other positional relationship. While the present embodiment illustrated an example where the rear cabinet 1 is constituted by three pieces 11, 12 and 13 having shapes obtained by cutting the entire rear cabinet 1 into pieces in the short side direction, the rear cabinet 1 may also be constituted by multiple pieces having other shapes. For example, the rear cabinet 1 may be constituted by two pieces, or may be constituted by four or more pieces. For another example, the rear cabinet 1 may be constituted by multiple pieces having shapes obtained by cutting the entire rear cabinet 1 into pieces in the long side direction, or may be constituted by multiple pieces obtained by cutting the entire rear cabinet 1 into pieces in the long side and short side directions. Also in such forms, the connection parts between the pieces have configurations similar to those in the present embodiment.

While the present embodiment illustrated an example where the display apparatus of the present invention is applied to a television receiver, the display apparatus may also take a form other than the above. For example, the display apparatus according to the present invention may be applied to an information display.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1-5. (canceled)

6. A display apparatus, comprising:
a rectangular display section for displaying an image on a front side;
a frame-shaped front cabinet located at the front side of the display section; and
a rectangular plate-shaped rear cabinet located on a rear side of the display section, wherein
the rear cabinet is constituted by connecting a plurality of rectangular plate-shaped pieces with a plurality of screws, parts of the pieces being overlapped with each other,
one of any two pieces to be connected among the plurality of the pieces, including:
a circumferential part along one side; and
a plurality of through holes into which the plurality of screws are inserted respectively, which are formed at a circumferential part,
the other of the two pieces, including:
an overlap part protruding from one side of a rear surface, in parallel with the rear surface, at a position closer to an front side than the rear surface so as to be overlapped with the front surface of the circumferential part;
a first rib provided on the front surface of the overlap part along said one side;
a parallel member, which is along said one side, protruding from the first rib to be in parallel with the rear surface in a same direction as the overlap part; and
a plurality of bosses provided being joined to a surface of the first rib on a side where the parallel member protrudes, each of the plurality of bosses being provided with a hole for receiving each of the plurality of screws at an end opposite to each of the plurality of through holes, and
the parallel member is disconnected at a portion of the first rib where one of the plurality of bosses is joined.

7. The display apparatus according to claim 6, wherein
the other of the two pieces, further includes
a second rib so bent as to enclose a reverse side of the first rib at the portion where one of the plurality of bosses is joined, which is provided on an front surface of the overlap part, and
the second rib is coupled to the reverse side of the first rib at a portion where the parallel member protrudes on both sides of the portion where one of the plurality of bosses is joined.

8. The display apparatus according to claim 7, wherein
the other of the two pieces, further includes
more than one of the second ribs.

9. The display apparatus according to claim 6, wherein
said one of the two pieces, further includes
a third rib being in parallel with the first rib and in contact with the parallel member, which is provided on the front surface.

10. The display apparatus according to claim 9, wherein
a portion at a protruding end of the overlap part is inclined from a rear side toward an front side.

11. The display apparatus according to claim 6, wherein
the other of the two pieces, further includes
a protruding part protruding from the first rib in a same direction as the overlap part, which is joined to the end of each of the plurality of bosses and has a predetermined length along said one side.

12. The display apparatus according to claim 11, wherein
said one of the two pieces, further includes
a third rib being in parallel with the first rib and in contact with the parallel member, which is provided on the front surface, and
a portion of the third rib opposite to the protruding part has a shape of avoiding the protruding part on the front surface of said one of the two pieces.

13. A television receiver, comprising:
the display apparatus according to claim 6; and
a receiving section for receiving television broadcasts, wherein
the display apparatus displays an image based on the television broadcasts received by the receiving section.
